(19) United States
(12) Patent Application Publication
(10) Pub. No.: US 2026/0371955 A1
(43) Pub. Date: Nov. 19, 2026

(54) METHOD FOR MODIFYING SILICON OXIDE FILM, AND SUBSTRATE PROCESSING APPARATUS

(71) Applicant: Tokyo Electron Limited, Tokyo (JP)

(72) Inventors: Shinichi IKE, Yamanashi (JP); Haruka OKOSHI, Yamanashi (JP); Genki HAYASHI, Yamanashi (JP); Tomohiro NAKAGAWA, Gyeonggi-do (KR); Shuji AZUMO, Yamanashi (JP)

(21) Appl. No.: 19/728,805

(22) Filed: Jul. 2, 2026

Related U.S. Application Data
(63) Continuation of application No. PCT/JP2024/043945, filed on Dec. 12, 2024.

(30) Foreign Application Priority Data
Jan. 18, 2024 (JP) 2024-005793

(51) Int. Cl. H10P 14/60

(52) U.S. Cl. CPC H10P 14/6532

(57) ABSTRACT

A method for modifying a silicon oxide film is provided and includes providing a substrate over which a silicon oxide film is formed; and modifying the silicon oxide film. The modification of the silicon oxide film includes exposing a surface of the silicon oxide film to a plasma formed from a first gas containing a hydrogen-containing gas; exposing the surface of the silicon oxide film to a plasma formed from a second gas free from a hydrogen-containing gas and containing an inert gas; and exposing the surface of the silicon oxide film to a plasma formed from a third gas containing a nitrogen-containing gas.

### CROSS-REFERENCE TO RELATED APPLICATIONS

This application is a continuation application of International Application No. PCT/JP2024/043945, filed on Dec. 12, 2024, and designated the U.S., which is based upon and claims priority to Japanese Patent Application No. 2024-005793, filed on Jan. 18, 2024, the entire contents of which are incorporated herein by reference.

### BACKGROUND

### 1. Field of the Invention

The present disclosure relates to a method for modifying a silicon oxide film, and a substrate processing apparatus.

### 2. Description of the Related Art

A technique of modifying a silicon oxide film by exposing a substrate, over which the silicon oxide film is formed, to both a plasma formed from a gas mixture of a hydrogen gas and an argon gas, and a plasma formed from an argon gas, is known (see, for example, Japanese Patent Application Publication No. 2023-182324).

### SUMMARY

A method for modifying a silicon oxide film according to an aspect of the present disclosure includes: providing a substrate over which a silicon oxide film is formed; and modifying the silicon oxide film. The modification of the silicon oxide film includes: (a) exposing a surface of the silicon oxide film to a plasma formed from a first gas containing a hydrogen-containing gas; (b) exposing the surface of the silicon oxide film to a plasma formed from a second gas free from a hydrogen-containing gas and containing an inert gas; and (c) exposing the surface of the silicon oxide film to a plasma formed from a third gas containing a nitrogen-containing gas.

### BRIEF DESCRIPTION OF THE DRAWINGS

FIG. 1 is a flowchart illustrating a method for modifying a silicon oxide film (hereinafter may also be referred to as “silicon oxide film modifying method”) according to a first embodiment of the present disclosure.

FIG. 2A is a cross-sectional diagram illustrating the silicon oxide film modifying method according to the first embodiment.

FIG. 2B is a cross-sectional diagram illustrating the silicon oxide film modifying method according to the first embodiment.

FIG. 2C is a cross-sectional diagram illustrating the silicon oxide film modifying method according to the first embodiment.

FIG. 2D is a cross-sectional diagram illustrating the silicon oxide film modifying method according to the first embodiment.

FIG. 3 is a flowchart illustrating an example of steps for forming the silicon oxide film.

FIG. 4 is a diagram illustrating an example of a processing system according to an embodiment of the present disclosure.

FIG. 5 is a diagram illustrating an example of a substrate processing apparatus according to an embodiment of the present disclosure.

FIG. 6 is a flowchart illustrating a silicon oxide film modifying method according to a second embodiment of the present disclosure.

FIG. 7 is a flowchart illustrating a silicon oxide film modifying method according to a third embodiment of the present disclosure.

FIG. 8 is a flowchart illustrating a silicon oxide film modifying method according to a fourth embodiment of the present disclosure.

FIG. 9 is a flowchart illustrating a silicon oxide film modifying method according to a fifth embodiment of the present disclosure.

FIG. 10 is a flowchart illustrating a silicon oxide film modifying method according to a sixth embodiment of the present disclosure.

FIG. 11 is a graph (1) illustrating a leak current density of the silicon oxide film.

FIG. 12 is a graph (2) illustrating the leak current density of the silicon oxide film.

FIG. 13 is a graph (3) illustrating the leak current density of the silicon oxide film.

### DETAILED DESCRIPTION OF THE DISCLOSURE

The present disclosure provides a technique capable of improving electrical characteristics of a silicon oxide film.

Hereinafter, non-limiting exemplary embodiments of the present disclosure will be described with reference to the drawings. In the drawings, the same or corresponding members or components are denoted by the same or corresponding reference signs, and thus duplicated descriptions thereof will be omitted.

### First Embodiment

### (Silicon Oxide Film Modifying Method)

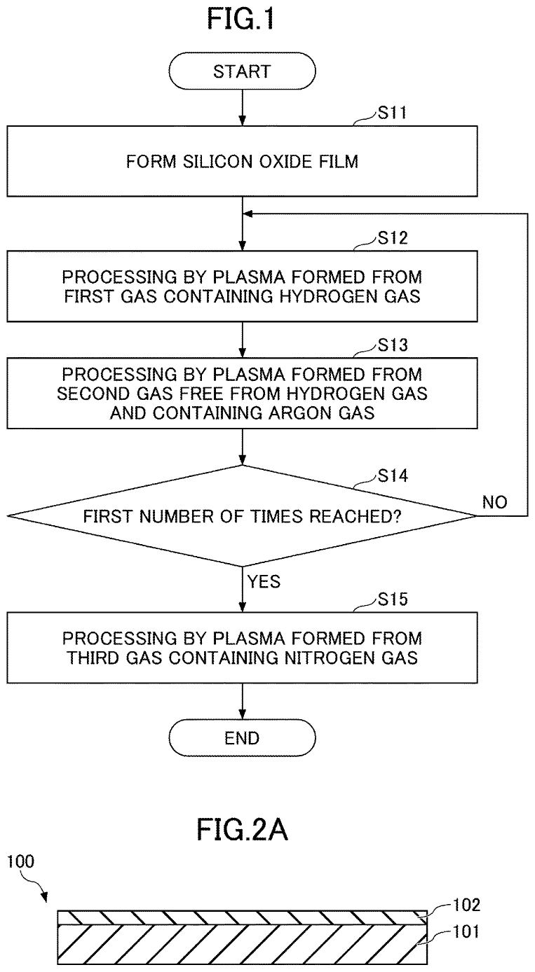

A silicon oxide film modifying method according to a first embodiment will be described with reference to FIGS. 1 to 3. The silicon oxide film modifying method according to the first embodiment includes steps S11 to S15 illustrated in FIG. 1.

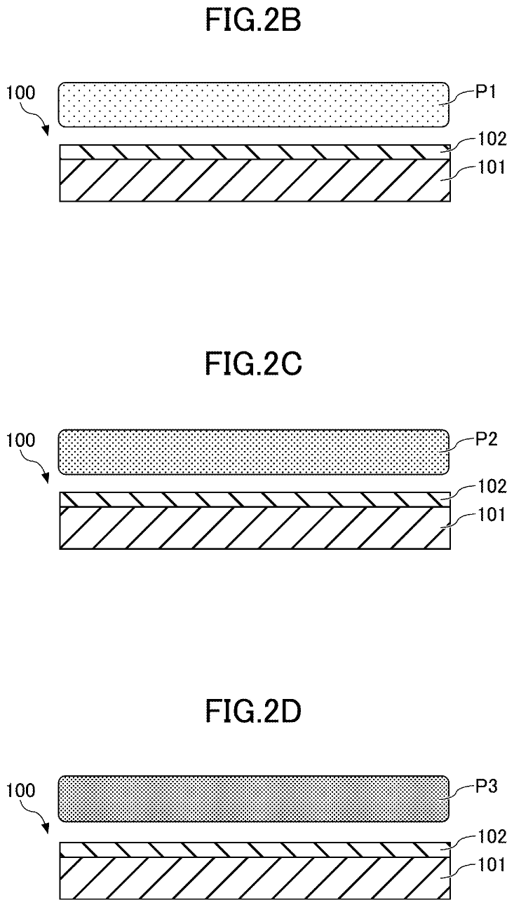

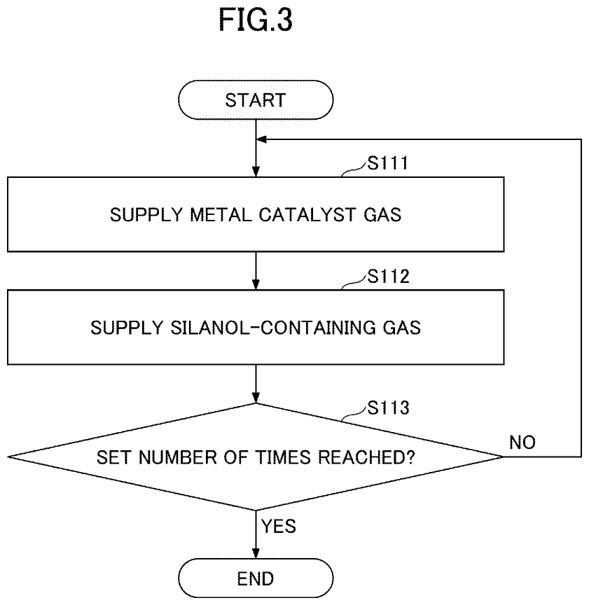

In step S11, as illustrated in FIG. 2A, a silicon oxide film 102 is formed over an insulating film 101, which is formed over a substrate 100. The insulating film 101 is, for example, a low-k film. No particular limitation is imposed on the type of the insulating film 101, and the insulating film 101 is, for example, an SiO film, an SiN film, an SiOC film, an SiON film, or an SiOCN film. The SiO film means a film containing silicon (Si) and oxygen (O). The atomic ratio between Si and O in the SiO film is not limited to 1:1. The same applies to the SiN film, the SiOC film, the SiON film, and the SiOCN film. Step S11 includes, for example, steps S111 to S113 illustrated in FIG. 3.

In step S111, a metal catalyst gas is supplied to the substrate 100, and the metal catalyst gas is adsorbed onto the insulating film 101. The metal catalyst gas is, for example, a trimethylaluminum (TMA) gas. In step S111, the substrate 100 is heated at a low temperature, e.g., 120 °C or higher and 300 °C or lower.

Step S112 is performed after step S111. In step S112, a silanol-containing gas is supplied to the substrate 100, and the silanol-containing gas is reacted with the metal catalyst gas adsorbed onto the insulating film 101, thereby forming the silicon oxide film 102. The silanol-containing gas is, for example, TPSOL (tris(tert-pentoxy)silanol) or TBSOL (tris(tert-butoxy)silanol). In step S112, the substrate 100 is heated at a low temperature, e.g., 120 °C or higher and 300 °C or lower.

Step S113 is performed after step S112. In step S113, it is determined whether or not steps S111 and S112 have been performed a set number of times. When steps S111 and S112 have not been performed the set number of times (NO in step S113), steps S111 and S112 are performed again. When steps S111 and S112 have been performed the set number of times (YES in step S113), the process is ended since the film thickness of the silicon oxide film 102 has reached a predetermined film thickness for plasma processing. The set number of times of step S113 is set in accordance with the deposition amount in order to achieve the predetermined film thickness of the silicon oxide film 102 formed in step S11. The deposition amount is adjustable, for example, in accordance with the supply amount of the silanol-containing gas. The predetermined film thickness is, for example, 2 nm or more and 5 nm or less. In this case, in steps S12 to S15, the plasma tends to be applied to the entirety of the silicon oxide film 102 in the film thickness direction of the silicon oxide film 102 formed in step S11, which is the previous step. Therefore, the entirety of the silicon oxide film 102 in the film thickness direction is modified. When the film thickness of the silicon oxide film 102 formed in step S11 is greater than the predetermined film thickness, the modification with the plasma tends not to be applied to regions located deep within the silicon oxide film 102 from the surface thereof in steps S12 to S15. The set number of times of step S113 may be one, or two or more.

Step S12 is performed after step S11. In step S12, as illustrated in FIG. 2B, the surface of the silicon oxide film 102 is exposed to a plasma P1 formed from a first gas containing a hydrogen gas. This removes impurities in the film, such as Si—OH bonds and the like. In step S12, when the silicon oxide film 102 is exposed to the plasma P1, hydrogen defects can be formed in the silicon oxide film 102 through reaction between the silicon oxide film 102 and active species contained in the plasma P1. The first gas may be mixed with an argon gas for use. In step S12, the substrate 100 may be heated at a temperature higher than the temperature in step S11. In this case, the impurities in the film, such as Si—OH bonds and the like, are readily removed.

An example of processing conditions for step S12 is as follows.
Flow rate of hydrogen gas: 200 sccm to 3,000 sccm
Flow rate of argon gas: 600 sccm to 6,000 sccm
Substrate temperature: 120 °C to 350 °C
Processing pressure: 1 Torr to 5 Torr (133 Pa to 667 Pa)
Processing time: 10 sec to 60 sec

Step S13 is performed after step S12. In step S13, as illustrated in FIG. 2C, the surface of the silicon oxide film 102 is exposed to a plasma P2 formed from a second gas free from a hydrogen gas and containing an argon gas. This removes the hydrogen defects formed in the silicon oxide film 102 in step S12. As a result, both the impurities in the film, such as Si—OH bonds and the like, and the hydrogen defects can be reduced. Therefore, the leak current of the silicon oxide film 102 can be readily reduced compared to the modification using the plasma P1 alone or the modification using the plasma P2 alone. In step S13, the substrate 100 may be heated at a temperature higher than the temperature in step S11. In this case, the hydrogen defects are readily removed. In the transition from step S12 to step S13, the plasma P1 may be switched to the plasma P2 while the plasma P1 is maintained, or the plasma P2 may be formed after the plasma P1 is stopped.

An example of processing conditions for step S13 is as follows.
Flow rate of argon gas: 600 sccm to 6,000 sccm
Substrate temperature: 120 °C to 350 °C
Processing pressure: 1 Torr to 5 Torr (133 Pa to 667 Pa)
Processing time: 10 sec to 60 sec

Step S14 is performed after step S13. In step S14, it is determined whether or not steps S12 and S13 have been performed a first number of times. When steps S12 and S13 have not been performed the first number of times (NO in step S14), steps S12 and S13 are performed again. Conversely, when steps S12 and S13 have been performed the first number of times (YES in step S14), the process proceeds to step S15. The first number of times is set, for example, in accordance with the film thickness of the silicon oxide film 102 formed in step S11. The first number of times may be one, or two or more. The first number of times is preferably two to six. In the transition from step S13 to step S12, the plasma P2 may be switched to the plasma P1 while the plasma P2 is maintained, or the plasma P1 may be formed after the plasma P2 is stopped.

In step S15, as illustrated in FIG. 2D, the surface of the silicon oxide film 102 is exposed to a plasma P3 formed from a third gas containing a nitrogen gas. This can further reduce the leak current of the silicon oxide film 102. This is likely because electrically active defects present on the surface and interior of the silicon oxide film 102 are inactivated by exposing the silicon oxide film 102 to the plasma P3. The third gas may contain an argon gas. The third gas may contain a hydrogen gas. A ratio of the flow rate of the nitrogen gas contained in the third gas may be 5% or more and 40% or less. In step S15, the substrate 100 may be heated at a temperature higher than the temperature in step S11. In this case, the leak current is readily reduced. In the transition from step S13 to step S15, the plasma P2 may be switched to the plasma P3 while the plasma P2 is maintained, or the plasma P3 may be formed after the plasma P2 is stopped.

An example of processing conditions for step S15 is as follows.
Flow rate of nitrogen gas: 200 sccm to 2,000 sccm
Flow rate of argon gas: 600 sccm to 6,000 sccm
Flow rate of hydrogen gas: 200 sccm to 2,000 sccm
Substrate temperature: 120 °C to 350 °C
Processing pressure: 1 Torr to 5 Torr (133 Pa to 667 Pa)
Processing time: 10 sec to 60 sec

As described above, the silicon oxide film modifying method according to the first embodiment includes: providing the substrate 100 over which the silicon oxide film 102 is formed; and modifying the silicon oxide film 102. The modification of the silicon oxide film 102 includes step S12, step S13, and step S15. In step S12, the surface of the silicon oxide film 102 is exposed to the plasma P1 formed from the first gas containing the hydrogen gas. In step S13, the surface of the silicon oxide film 102 is exposed to the plasma P2 formed from the second gas free from the hydrogen gas and containing the argon gas. In step S15, the surface of the silicon oxide film 102 is exposed to the plasma P3 formed from the third gas containing the nitrogen gas. In this case, the leak current of the silicon oxide film 102 can be reduced. That is, the electrical characteristics of the silicon oxide film 102 can be improved.

### (Processing System)

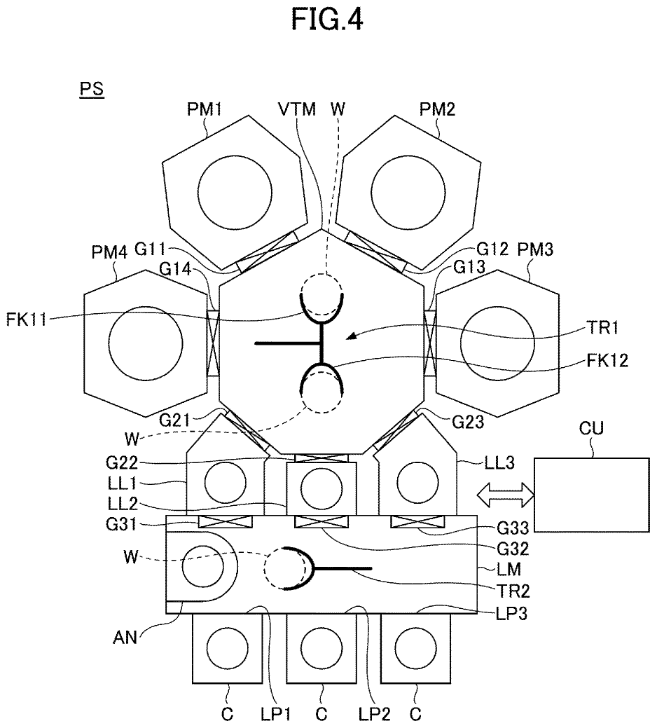

An example of a processing system PS configured to perform the silicon oxide film modifying method according to the first embodiment will be described with reference to FIG. 4.

The processing system PS includes processors PM1 to PM4, a vacuum transfer chamber VTM, load-lock chambers LL1 to LL3, an atmospheric transfer chamber LM, load ports LP1 to LP3, and an overall control unit CU.

The processors PM1 to PM4 are connected to the vacuum transfer chamber VTM via gate valves G11 to G14, respectively. The interior of each of the processors PM1 to PM4 is reduceable in pressure to a predetermined vacuum atmosphere. Each of the processors PM1 to PM4 is configured to house a substrate W and perform desired processing on the substrate W.

The interior of the vacuum transfer chamber VTM is reduceable in pressure to a predetermined vacuum atmosphere. The vacuum transfer chamber VTM is provided with a first transfer apparatus TR1 configured to transfer the substrate W under reduced pressure. The first transfer apparatus TR1 transfers the substrate W to the processors PM1 to PM4 and the load-lock chambers LL1 to LL3. The first transfer apparatus TR1 includes, for example, two transfer arms FK11 and FK12, which are movable independently.

The load-lock chambers LL1 to LL3 are connected to the vacuum transfer chamber VTM via gate valves G21 to G23, respectively. The load-lock chambers LL1 to LL3 are connected to the atmospheric transfer chamber LM via gate valves G31 to G33, respectively. The load-lock chambers LL1 to LL3 are switchable between an atmospheric-pressure atmosphere and a vacuum atmosphere.

The interior of the atmospheric transfer chamber LM is an atmospheric-pressure atmosphere. In the interior of the atmospheric transfer chamber LM, for example, a downflow of clean air is formed. An aligner AN configured to perform alignment of the substrate W is provided in the interior of the atmospheric transfer chamber LM. The aligner AN may be provided outside of the atmospheric transfer chamber LM. A second transfer apparatus TR2 is provided in the atmospheric transfer chamber LM. The second transfer apparatus TR2 is configured to transfer the substrate W to the load-lock chambers LL1 to LL3, the load ports LP1 to LP3, and the aligner AN.

The load ports LP1 to LP3 are provided on the wall surface of the longitudinal side of the atmospheric transfer chamber LM. Carriers C are attached to the load ports LP1 to LP3. The carriers C include a carrier C in which the substrate W is housed, and an empty carrier C. The carrier C may be, for example, a FOUP (Front Opening Unified Pod).

The overall control unit CU may be, for example, a computer. The overall control unit CU includes a CPU (Central Processing Unit), a RAM (Random Access Memory), a ROM (Read Only Memory), and an auxiliary storage device. The CPU is configured to operate in accordance with a program stored in the ROM or the auxiliary storage device, and to control each component of the processing system PS. For example, the overall control unit CU controls operations of the processors PM1 to PM4, the first transfer apparatus TR1, the second transfer apparatus TR2, the gate valves G11 to G14, G21 to G23, and G31 to G33. For example, the overall control unit CU controls an operation to switch the interior of the load-lock chambers LL1 to LL3 between an atmospheric-pressure atmosphere and a vacuum atmosphere.

Next, the operation of the processing system PS will be described. First, the second transfer apparatus TR2 takes out the substrate W from the carrier C, transfers the taken-out substrate W to the aligner AN, and exits the aligner AN. Next, the aligner AN performs alignment of the substrate W. Next, the second transfer apparatus TR2 takes out the substrate W from the aligner AN, transfers the taken-out substrate W to the load-lock chamber LL1, and exits the load-lock chamber LL1. Next, the interior of the load-lock chamber LL1 is switched from the atmospheric-pressure atmosphere to the vacuum atmosphere. Subsequently, the first transfer apparatus TR1 takes out the substrate W from the load-lock chamber LL1, and transfers the taken-out substrate W to the processor PM1.

Next, the processor PM1 performs steps S11 to S15 in the silicon oxide film modifying method according to the first embodiment.

Next, the first transfer apparatus TR1 takes out the substrate W from the processor PM1, transfers the taken-out substrate W to the load-lock chamber LL3, and exits the load-lock chamber LL3. Next, the interior of the load-lock chamber LL3 is switched from the vacuum atmosphere to the atmospheric-pressure atmosphere. Subsequently, the second transfer apparatus TR2 takes out the substrate W from the load-lock chamber LL3, and stores the taken-out substrate W in the carrier C. At this point, the processing of the substrate W is ended.

The operation of the processing system PS has been described above using the case in which steps S11 to S15 are performed using the single processor PM1. However, this is by no means a limitation. For example, steps S11 to S15 may be performed using at least one of the other processors PM2 to PM4. For example, steps S11 to S15 may be performed using two or more of the four processors PM1 to PM4. For example, step S11 may be performed using the processor PM1, and steps S12 to S15 may be performed using the processor PM2. In this case, when step S11 and steps S12 to S15 are performed at different temperatures, it is possible to reduce the time required for changing the temperature, which leads to improvement in productivity.

### (Substrate Processing Apparatus)

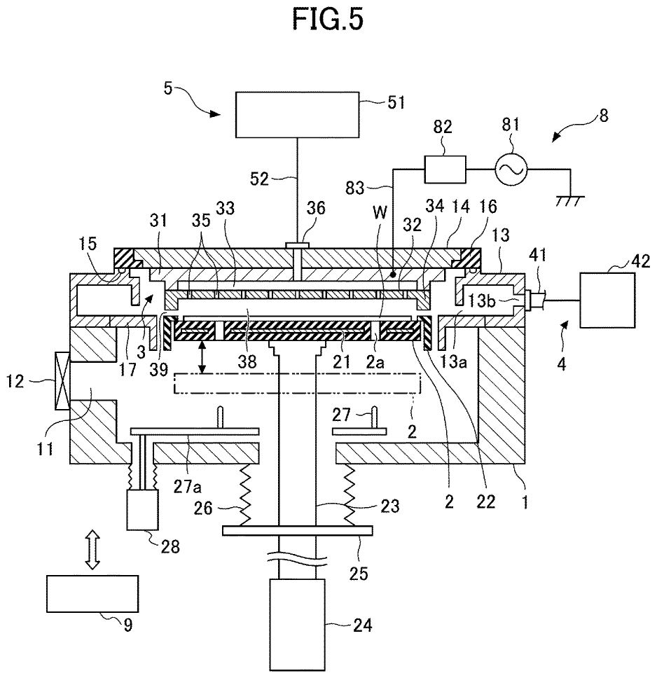

An example of the substrate processing apparatus used as the processors PM1 to PM4 included in the processing system PS illustrated in FIG. 4 will be described with reference to FIG. 5.

The substrate processing apparatus includes a processing chamber 1, a stage 2, a shower head 3, a gas exhauster 4, a gas supply 5, an RF power supply 8, and a controller 9 (an example of control circuitry).

The processing chamber 1 is formed of a metal, such as aluminum or the like, and has a substantially cylindrical shape. The processing chamber 1 is configured to house the substrate W. The substrate W may be, for example, a semiconductor wafer. A transfer port 11 for transferring in or out the substrate W is formed in a side wall of the processing chamber 1. The transfer port 11 is opened and closed by a gate valve 12. An annular gas exhaust duct 13 having a rectangular cross section is provided on the body of the processing chamber 1. A slit 13a is formed along the inner peripheral surface of the gas exhaust duct 13. A gas exhaust port 13b is formed in the outer wall of the gas exhaust duct 13. A top wall 14 is provided on the top surface of the gas exhaust duct 13 to close the upper opening of the processing chamber 1 via an insulating member 16. A space between the gas exhaust duct 13 and the insulating member 16 is airtightly sealed by a sealing member 15. The sealing member 15 may be, for example, an O-ring. A partitioning member 17 is configured to vertically partition the interior of the processing chamber 1 when the stage 2 (and a cover 22) is raised to a processing position, which will be described below.

The stage 2 is configured to horizontally support the substrate W in the processing chamber 1. The stage 2 has a disk shape. For example, the outer diameter of the stage 2 is greater than the outer diameter of the substrate W. The stage 2 is formed of a ceramic material, such as AlN or the like, or of a metal material, such as aluminum, a nickel alloy, or the like. A heater 21 configured to heat the substrate W is embedded in the stage 2. The heater 21 generates heat by power supplied from a heater power supply (not shown). A thermocouple (not shown) is provided near the top surface of the stage 2. By controlling the output of the heater 21 in accordance with a temperature signal of the thermocouple, the substrate W is controlled to a predetermined temperature. The stage 2 is provided with the cover 22 formed of ceramics, such as alumina or the like, to cover the side surface and the outer peripheral region of the top surface.

A support 23 is provided on the bottom surface of the stage 2. The support 23 is configured to support the stage 2. The support 23 extends from the center of the bottom surface of the stage 2 downward from the processing chamber 1 through a hole formed in the bottom wall of the processing chamber 1. The lower end of the support 23 is connected to a raising and lowering mechanism 24. The raising and lowering mechanism 24 is configured to raise and lower the stage 2 using the support 23 between the processing position and a transfer position, which are illustrated in FIG. 5. The transfer position is disposed below the processing position, and indicated by a two-dot chain line. The substrate W can be transferred at the transfer position. A flange 25 is attached to a portion of the support 23 that is below the processing chamber 1. A bellows 26 is provided between the flange 25 and the bottom surface of the processing chamber 1. The bellows 26 is configured to separate the internal atmosphere of the processing chamber 1 from the external atmosphere, and extend and contract in accordance with the raising and lowering operation of the stage 2.

Three support pins 27 (only two are illustrated) are provided near the bottom surface of the processing chamber 1 to project upward from a raising and lowering plate 27a. The support pins 27 are configured to be raised and lowered via the raising and lowering plate 27a by a raising and lowering mechanism 28, which is provided below the processing chamber 1. The support pins 27 are projectable and retractable with respect to the top surface of the stage 2 by being inserted into through-holes 2a in the stage 2, which is located at the processing position. By raising and lowering the support pins 27, the substrate W is delivered between the first transfer apparatus TR1 (FIG. 4) and the stage 2.

The shower head 3 is configured to supply a processing gas into the processing chamber 1 in the form of shower. The shower head 3 is formed of a metal, and is provided to face the stage 2. The diameter of the shower head 3 is substantially the same as the diameter of the stage 2. The shower head 3 includes a body 31 and a shower plate 32. The body 31 is fixed to the top wall 14 of the processing chamber 1. The shower plate 32 is connected to the underside of the body 31. A gas diffusion space 33 is formed between the body 31 and the shower plate 32. The gas diffusion space 33 is provided with a gas introduction hole 36 penetrating through the center of the top wall 14 and the body 31. An annular projection 34 projecting downward is formed at the peripheral edge of the shower plate 32. Gas discharge holes 35 are formed in a flat portion inside of the annular projection 34. In a state in which the stage 2 is located at the processing position, a processing space 38 is formed between the stage 2 and the shower plate 32, and the top surface of the cover 22 and the annular projection 34 are in proximity to each other thereby forming an annular gap 39.

The gas exhauster 4 is configured to exhaust the internal gas of the processing chamber 1. The gas exhauster 4 includes a gas exhaust tube 41 and a gas exhaust mechanism 42. The gas exhaust tube 41 is connected to the gas exhaust port 13b. The gas exhaust mechanism 42 includes a pressure control valve, and a vacuum pump connected to the gas exhaust tube 41. During processing, an internal gas of the processing chamber 1 reaches the gas exhaust duct 13 through the slit 13a, and is exhausted by the gas exhaust mechanism 42 from the gas exhaust duct 13 through the gas exhaust tube 41.

The gas supply 5 is configured to supply various processing gases to the shower head 3. The gas supply 5 includes a gas source 51 and a gas line 52. The gas source 51 includes supply sources of various processing gases, a mass flow controller, and a valve. The various processing gases include gases used, at least, in the silicon oxide film modifying method according to the first embodiment. The various gases are introduced from the gas source 51 into the gas diffusion space 33 through the gas line 52 and the gas introduction hole 36.

The substrate processing apparatus is a capacitively coupled plasma apparatus in which the stage 2 functions as a lower electrode and the shower head 3 functions as an upper electrode. The stage 2 is grounded. The shower head 3 is connected to the RF power supply 8.

The RF power supply 8 is configured to supply high-frequency power (hereinafter also referred to as “RF power”) to the shower head 3. The RF power supply 8 includes an RF power supply 81, a matcher 82, and a power supply line 83. The RF power supply 81 is a power supply configured to generate RF power. The RF power has a frequency suitable for forming a plasma. The frequency of the RF power is, for example, a frequency within a range from 450 KHz in a low-frequency band to 2.45 GHz in a microwave band. The RF power supply 81 is connected to the body 31 via the matcher 82 and the power supply line 83. The matcher 82 includes a circuit configured to match the load impedance to the internal impedance of the RF power supply 81. The RF power supply 8 may be configured to supply RF power to the stage 2.

The controller 9 is, for example, a computer. The controller 9 includes a CPU (Central Processing Unit), a RAM (Random Access Memory), a ROM (Read Only Memory), an auxiliary storage device, and the like. The CPU operates in accordance with a program stored in the ROM or the auxiliary storage device, and controls the operation of the substrate processing apparatus. The controller 9 may be provided inside or outside of the substrate processing apparatus. When the controller 9 is provided outside of the substrate processing apparatus, the controller 9 can control the substrate processing apparatus by a communication method, such as a wired or wireless communication method, or the like.

### Second Embodiment

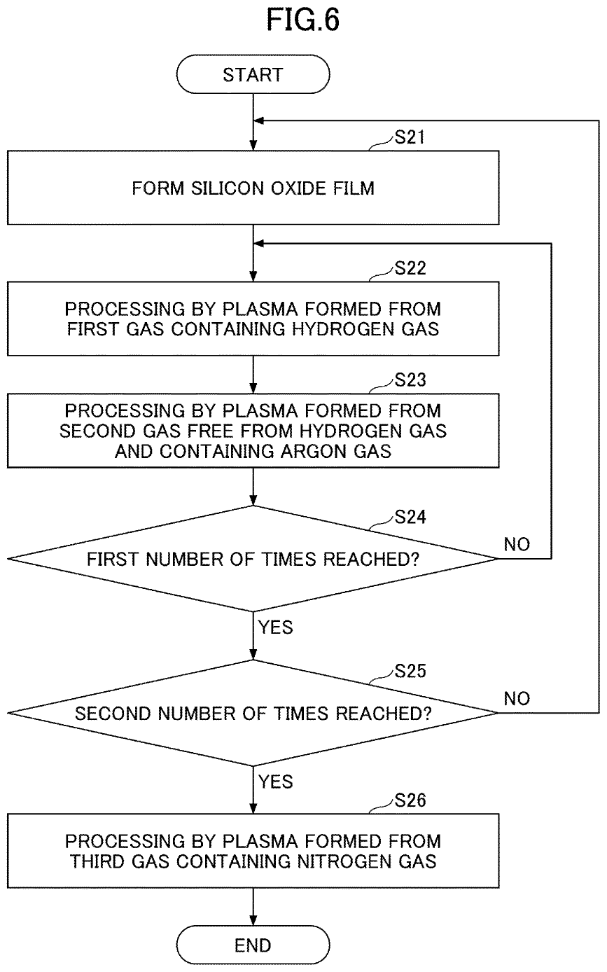

A silicon oxide film modifying method according to a second embodiment will be described with reference to FIG. 6. The silicon oxide film modifying method according to the second embodiment includes steps S21 to S26 illustrated in FIG. 6. Steps S21 to S24 are the same as steps S11 to S14. Step S26 is the same as step S15.

Step S25 is performed when it is determined in step S24 that steps S22 and S23 have been performed a first number of times (YES in step S24). In step S25, it is determined whether or not steps S21 to S24 have been performed a second number of times. When steps S21 to S24 have not been performed the second number of times (NO in step S25), steps S21 to S24 are performed again. Conversely, when steps S21 to S24 have been performed the second number of times (YES in step S25), the process proceeds to step S26. The second number of times is set, for example, in accordance with the target film thickness of the silicon oxide film 102. The second number of times may be one, or two or more.

As described above, the silicon oxide film modifying method according to the second embodiment includes: providing the substrate 100 over which the silicon oxide film 102 is formed; and modifying the silicon oxide film 102. The modification of the silicon oxide film 102 includes step S22, step S23, and step S26. In step S22, the surface of the silicon oxide film 102 is exposed to the plasma P1 formed from the first gas containing the hydrogen gas. In step S23, the surface of the silicon oxide film 102 is exposed to the plasma P2 formed from the second gas free from the hydrogen gas and containing the argon gas. In step S26, the surface of the silicon oxide film 102 is exposed to the plasma P3 formed from the third gas containing the nitrogen gas. In this case, the leak current of the silicon oxide film 102 can be reduced similar to the silicon oxide film modifying method according to the first embodiment. That is, the electrical characteristics of the silicon oxide film 102 can be improved.

The silicon oxide film modifying method according to the second embodiment can be performed using the processing system PS according to the first embodiment similar to the silicon oxide film modifying method according to the first embodiment.

### Third Embodiment

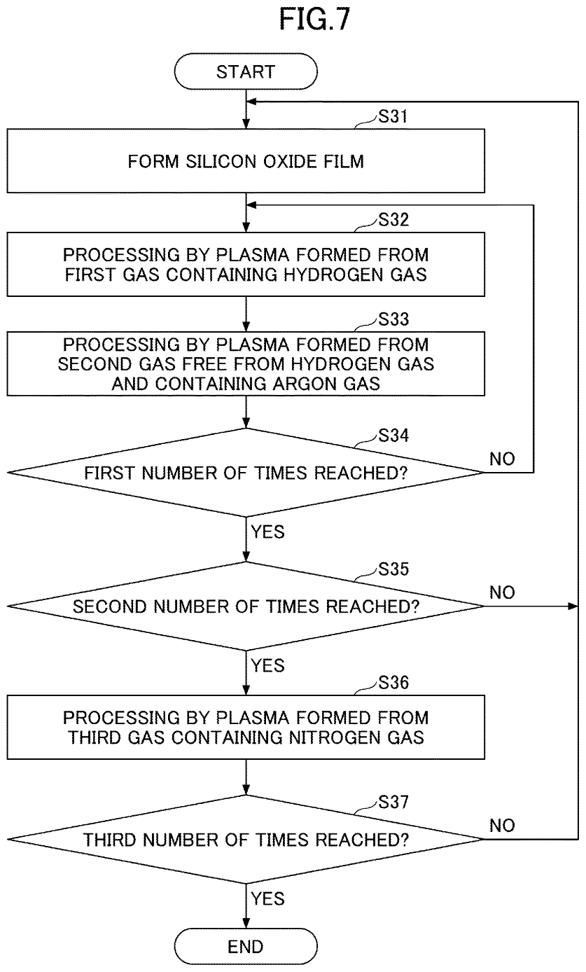

A silicon oxide film modifying method according to a third embodiment will be described with reference to FIG. 7. The silicon oxide film modifying method according to the third embodiment includes steps S31 to S37 illustrated in FIG. 7. Steps S31 to S34 are the same as steps S11 to S14. Step S35 is the same as step S25. Step S36 is the same as step S15.

Step S37 is performed after step S36. In step S37, it is determined whether or not steps S31 to S36 have been performed a third number of times. When steps S31 to S36 have not been performed the third number of times (NO in step S37), steps S31 to S36 are performed again. Conversely, when steps S31 to S36 have been performed the third number of times (YES in step S37), the process is ended. The third number of times is set, for example, in accordance with the target film thickness of the silicon oxide film 102. The third number of times may be one, or two or more.

As described above, the silicon oxide film modifying method according to the third embodiment includes: providing the substrate 100 over which the silicon oxide film 102 is formed; and modifying the silicon oxide film 102. The modification of the silicon oxide film 102 includes step S32, step S33, and step S36. In step S32, the surface of the silicon oxide film 102 is exposed to the plasma P1 formed from the first gas containing the hydrogen gas. In step S33, the surface of the silicon oxide film 102 is exposed to the plasma P2 formed from the second gas free from the hydrogen gas and containing the argon gas. In step S36, the surface of the silicon oxide film 102 is exposed to the plasma P3 formed from the third gas containing the nitrogen gas. In this case, the leak current of the silicon oxide film 102 can be reduced similar to the silicon oxide film modifying method according to the first embodiment. That is, the electrical characteristics of the silicon oxide film 102 can be improved.

The silicon oxide film modifying method according to the third embodiment can be performed using the processing system PS according to the first embodiment similar to the silicon oxide film modifying method according to the first embodiment.

### Fourth Embodiment

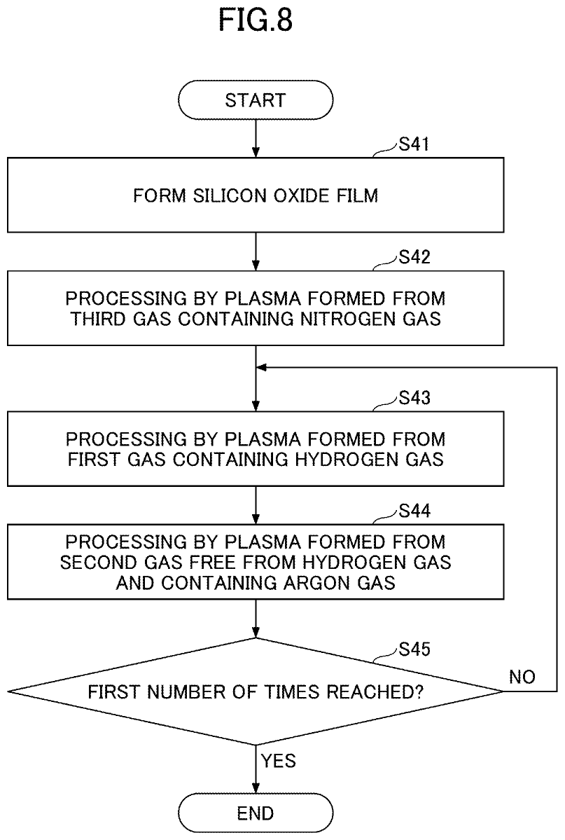

A silicon oxide film modifying method according to a fourth embodiment will be described with reference to FIG. 8. The silicon oxide film modifying method according to the fourth embodiment includes steps S41 to S45 illustrated in FIG. 8. The silicon oxide film modifying method according to the fourth embodiment differs from the silicon oxide film modifying method according to the first embodiment in that the surface of the silicon oxide film 102 is exposed sequentially to the plasma P3, the plasma P1, and the plasma P2.

Step S41 is the same as step S11. Step S42 is the same as step S15. Steps S43 to S45 are the same as steps S12 to S14.

As described above, the silicon oxide film modifying method according to the fourth embodiment includes: providing the substrate 100 over which the silicon oxide film 102 is formed; and modifying the silicon oxide film 102. The modification of the silicon oxide film 102 includes step S43, step S44, and step S42. In step S43, the surface of the silicon oxide film 102 is exposed to the plasma P1 formed from the first gas containing the hydrogen gas. In step S44, the surface of the silicon oxide film 102 is exposed to the plasma P2 formed from the second gas free from the hydrogen gas and containing the argon gas. In step S42, the surface of the silicon oxide film 102 is exposed to the plasma P3 formed from the third gas containing the nitrogen gas. In this case, the leak current of the silicon oxide film 102 can be reduced similar to the silicon oxide film modifying method according to the first embodiment. That is, the electrical characteristics of the silicon oxide film 102 can be improved.

The silicon oxide film modifying method according to the fourth embodiment can be performed using the processing system PS according to the first embodiment similar to the silicon oxide film modifying method according to the first embodiment.

### Fifth Embodiment

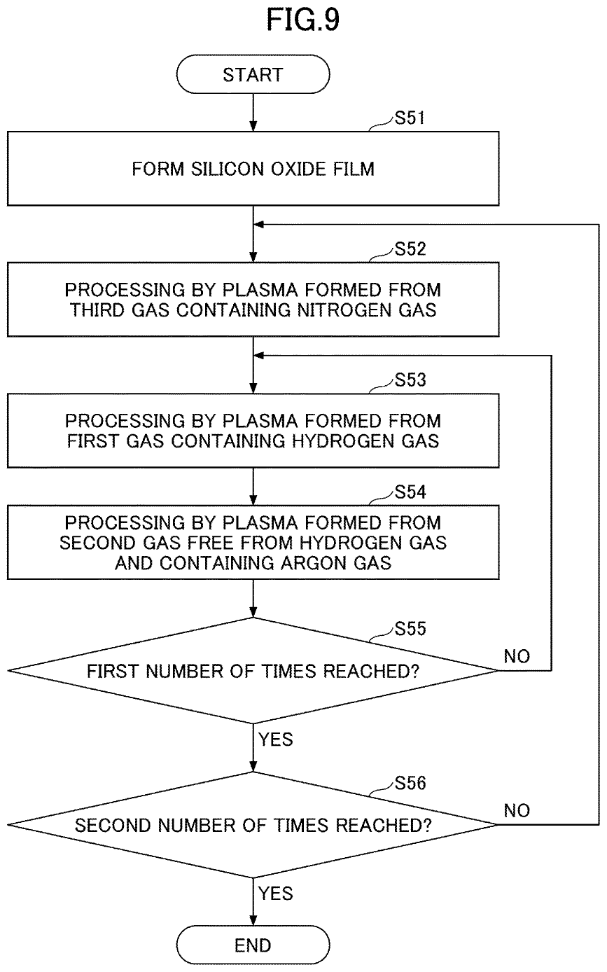

A silicon oxide film modifying method according to a fifth embodiment will be described with reference to FIG. 9. The silicon oxide film modifying method according to the fifth embodiment includes steps S51 to S56 illustrated in FIG. 9. Steps S51 to S55 are the same as steps S41 to S45.

Step S56 is performed when it is determined in step S55 that steps S53 and S54 have been performed a first number of times (YES in step S55). In step S56, it is determined whether or not steps S52 to S55 have been performed a second number of times. When steps S52 to S55 have not been performed the second number of times (NO in step S56), steps S52 to S55 are performed again. Conversely, when steps S52 to S55 have been performed the second number of times (YES in step S56), the process is ended. The second number of times is set, for example, in accordance with the film thickness of the silicon oxide film 102 formed in step S51. The second number of times may be one, or two or more.

As described above, the silicon oxide film modifying method according to the fifth embodiment includes: providing the substrate 100 over which the silicon oxide film 102 is formed; and modifying the silicon oxide film 102. The modification of the silicon oxide film 102 includes step S53, step S54, and step S52. In step S53, the surface of the silicon oxide film 102 is exposed to the plasma P1 formed from the first gas containing the hydrogen gas. In step S54, the surface of the silicon oxide film 102 is exposed to the plasma P2 formed from the second gas free from the hydrogen gas and containing the argon gas. In step S52, the surface of the silicon oxide film 102 is exposed to the plasma P3 formed from the third gas containing the nitrogen gas. In this case, the leak current of the silicon oxide film 102 can be reduced similar to the silicon oxide film modifying method according to the first embodiment. That is, the electrical characteristics of the silicon oxide film 102 can be improved.

The silicon oxide film modifying method according to the fifth embodiment can be performed using the processing system PS according to the first embodiment similar to the silicon oxide film modifying method according to the first embodiment.

### Sixth Embodiment

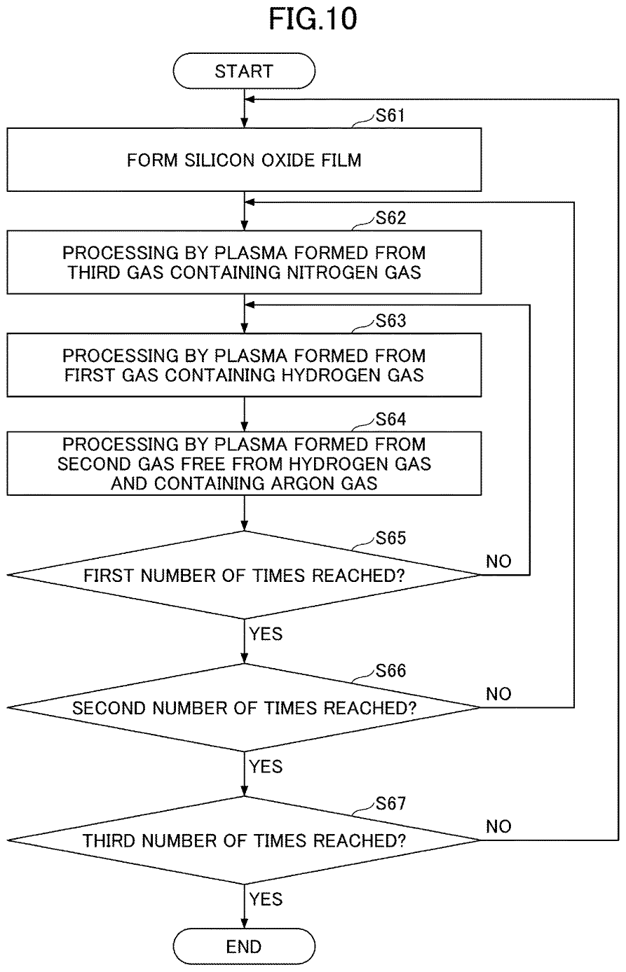

A silicon oxide film modifying method according to a sixth embodiment will be described with reference to FIG. 10. The silicon oxide film modifying method according to the sixth embodiment includes steps S61 to S67 illustrated in FIG. 10. Steps S61 to S66 are the same as steps S51 to S56.

Step S67 is performed when it is determined in step S66 that steps S62 to S65 have been performed a second number of times (YES in step S66). In step S67, it is determined whether or not steps S61 to S66 have been performed a third number of times. When steps S61 to S66 have not been performed the third number of times (NO in step S67), steps S61 to S66 are performed again. Conversely, when steps S61 to S66 have been performed the third number of times (YES in step S67), the process is ended. The third number of times is set, for example, in accordance with the target film thickness of the silicon oxide film 102. The third number of times may be one, or two or more.

As described above, the silicon oxide film modifying method according to the sixth embodiment includes: providing the substrate 100 over which the silicon oxide film 102 is formed; and modifying the silicon oxide film 102. The modification of the silicon oxide film 102 includes step S63, step S64, and step S62. In step S63, the surface of the silicon oxide film 102 is exposed to the plasma P1 formed from the first gas containing the hydrogen gas. In step S64, the surface of the silicon oxide film 102 is exposed to the plasma P2 formed from the second gas free from the hydrogen gas and containing the argon gas. In step S62, the surface of the silicon oxide film 102 is exposed to the plasma P3 formed from the third gas containing the nitrogen gas. In this case, the leak current of the silicon oxide film 102 can be reduced similar to the silicon oxide film modifying method according to the first embodiment. That is, the electrical characteristics of the silicon oxide film 102 can be improved.

The silicon oxide film modifying method according to the sixth embodiment can be performed using the processing system PS according to the first embodiment similar to the silicon oxide film modifying method according to the first embodiment.

### EXAMPLES

### Example 1

In Example 1, formation of a silicon oxide film over a substrate and modification of the silicon oxide film were sequentially performed three times. In the formation of the silicon oxide film and the modification of the silicon oxide film, the substrate temperature was fixed to 130 °C.

In the formation of the silicon oxide film, a TMA gas was supplied to the substrate and then a TPSOL gas was supplied to the substrate, thereby forming the silicon oxide film over the substrate. The TMA gas is an example of the metal catalyst gas. The TPSOL gas is an example of the silanol-containing gas.

In the modification of the silicon oxide film, first, exposure of the surface of the silicon oxide film to a plasma formed from a hydrogen gas and an argon gas, and exposure of the surface of the silicon oxide film to a plasma formed from an argon gas were sequentially performed three times. Next, the surface of the silicon oxide film was exposed to a plasma formed from a nitrogen gas, an argon gas, and a hydrogen gas. Hereinafter, the process of repeatedly performing sequentially the exposure of the surface of the silicon oxide film to the plasma formed from the hydrogen gas and the argon gas, and the exposure of the surface of the silicon oxide film to the plasma formed from the argon gas is also referred to as a cyclic plasma process. The process of exposing the surface of the silicon oxide film to the plasma formed from the nitrogen gas, the argon gas, and the hydrogen gas is also referred to as a nitrogen plasma process.

The period of the nitrogen plasma process per one time was fixed to 15 seconds. In the nitrogen plasma process, the flow rate ratio between the nitrogen gas and the hydrogen gas was changed by changing the flow rate of the nitrogen gas and the flow rate of the hydrogen gas while the flow rate of the argon gas was fixed to 3,000 sccm and the total flow rate of the nitrogen gas and the hydrogen gas was fixed to 2,000 sccm.

Next, the film thickness and leak current density of the silicon oxide film formed over the substrate were measured. A spectroscopic ellipsometer was used for the measurement of the film thickness. A mercury probe was used for the measurement of the leak current density. The leak current density was defined as a density of current flowing through the silicon oxide film when electric fields of 5 MV/cm and 3 MV/cm were applied to the silicon oxide film. The electric fields were determined by dividing the applied voltage by the film thickness. The current density was determined by dividing the measured current at the applied voltage by the electrode area of the mercury probe.

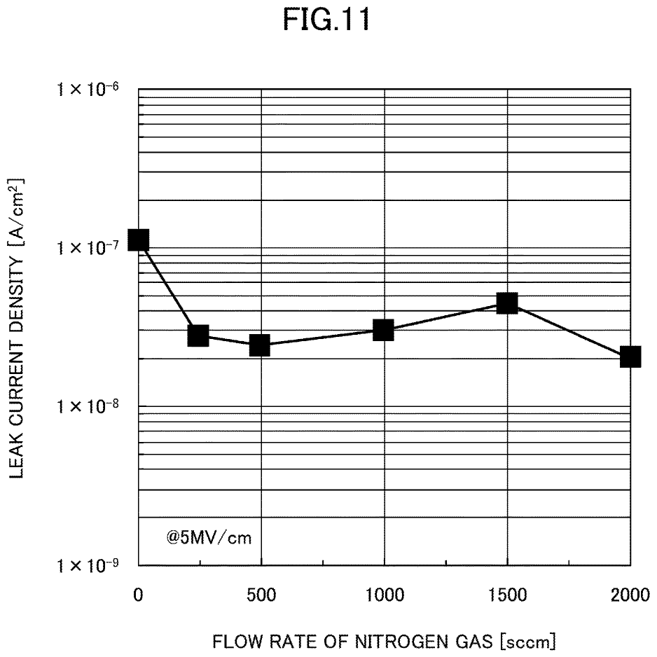

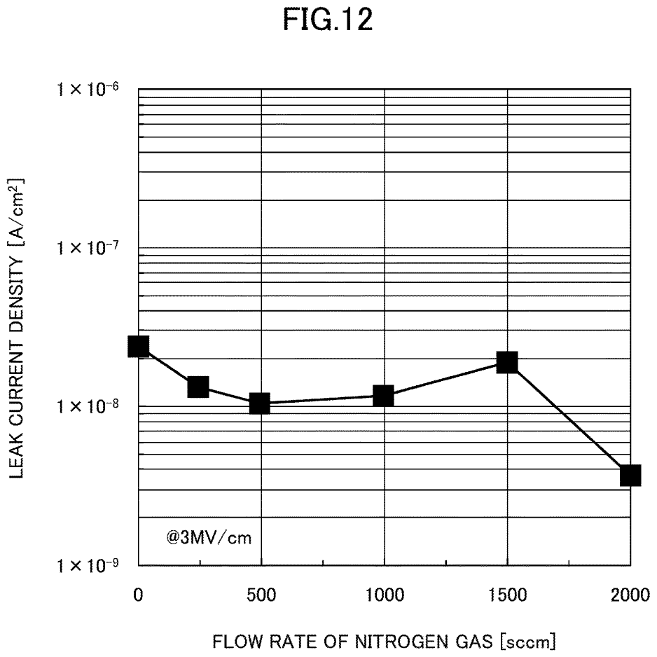

FIGS. 11 and 12 are graphs illustrating the leak current density of the silicon oxide film. Specifically, FIG. 11 is a graph illustrating the leak current density when the electric field of 5 MV/cm was applied to the silicon oxide film. FIG. 12 is a graph illustrating the leak current density when the electric field of 3 MV/cm was applied to the silicon oxide film. In FIGS. 11 and 12, the horizontal axis indicates the flow rate [sccm] of the nitrogen gas, and the vertical axis indicates the leak current density [A/cm²] of the silicon oxide film.

As illustrated in FIG. 11, when the flow rate of the nitrogen gas in the nitrogen plasma process was 0 sccm, 250 sccm, 500 sccm, 1,000 sccm, 1,500 sccm, and 2,000 sccm, the leak current density of the silicon oxide film was 1.1×10⁻⁷ A/cm², 2.8×10⁻⁸ A/cm², 2.4×10⁻⁸ A/cm², 3.0×10⁻⁸ A/cm², 4.5×10⁻⁸ A/cm², and 2.0×10⁻⁸ A/cm², respectively.

The leak current density of the silicon oxide film was lower when the flow rate of the nitrogen gas in the nitrogen plasma process was 250 sccm to 2,000 sccm than when the flow rate of the nitrogen gas in the nitrogen plasma process was 0 sccm. This result indicates that the leak current of the silicon oxide film can be reduced by performing the nitrogen plasma process after the cyclic plasma process.

When the flow rate of the nitrogen gas in the nitrogen plasma process was 250 sccm to 2,000 sccm, no significant difference was not found in the leak current density of the silicon oxide film. This result indicates that the leak current of the silicon oxide film can be reduced regardless of the flow rate of the nitrogen gas in the nitrogen plasma process.

As illustrated in FIG. 12, when the flow rate of the nitrogen gas in the nitrogen plasma process was 0 sccm, 250 sccm, 500 sccm, 1,000 sccm, 1,500 sccm, and 2,000 sccm, the leak current density of the silicon oxide film was 2.3×10⁻⁸ A/cm², 1.3×10⁻⁸ A/cm², 1.0×10⁻8 A/cm², 1.1×10⁻⁸ A/cm², 1.8×10⁻⁸ A/cm², and 3.6×10⁻⁹ A/cm², respectively.

The leak current density of the silicon oxide film was lower when the flow rate of the nitrogen gas in the nitrogen plasma process was 2,000 sccm than when the flow rate of the nitrogen gas in the nitrogen plasma process was 250 sccm, 500 sccm, 1,000 sccm, and 1,500 sccm. This result indicates that the leak current of the silicon oxide film can be reduced more when the hydrogen gas is not contained in the nitrogen plasma process than when the hydrogen gas is contained in the nitrogen plasma process.

### Example 2

In Example 2, formation of a silicon oxide film over a substrate and modification of the silicon oxide film were sequentially performed three times. In the formation of the silicon oxide film and the modification of the silicon oxide film, the substrate temperature was fixed to 130 °C. The formation of the silicon oxide film was similar to that in Example 1.

In the modification of the silicon oxide film, the silicon oxide film was modified under the following conditions 2A to 2E.

### <Condition 2A>

After the cyclic plasma process was performed, the nitrogen plasma process was performed.

### <Condition 2B>

After the nitrogen plasma process was performed, the cyclic plasma process was performed.

### <Condition 2C>

The nitrogen plasma process was not performed, and the cyclic plasma process alone was performed.

### <Condition 2D>

The cyclic plasma process was not performed, and the nitrogen plasma process alone was performed.

### <Condition 2E>

The cyclic plasma process and the nitrogen plasma process were not performed.

In the conditions 2A to 2E, the flow rate of the nitrogen gas, the flow rate of the hydrogen gas, and the flow rate of the argon gas in the nitrogen plasma process were set to 250 sccm, 1,750 sccm, and 3,000 sccm, respectively.

Next, the film thickness and leak current density of the silicon oxide film formed over the substrate were measured. A spectroscopic ellipsometer was used for the measurement of the film thickness. A mercury probe was used for the measurement of the leak current density. The leak current density was defined as a density of current flowing through the silicon oxide film when an electric field of 5 MV/cm was applied to the silicon oxide film. The electric field was determined by dividing the applied voltage by the film thickness. The current density was determined by dividing the measured current at the applied voltage by the electrode area of the mercury probe.

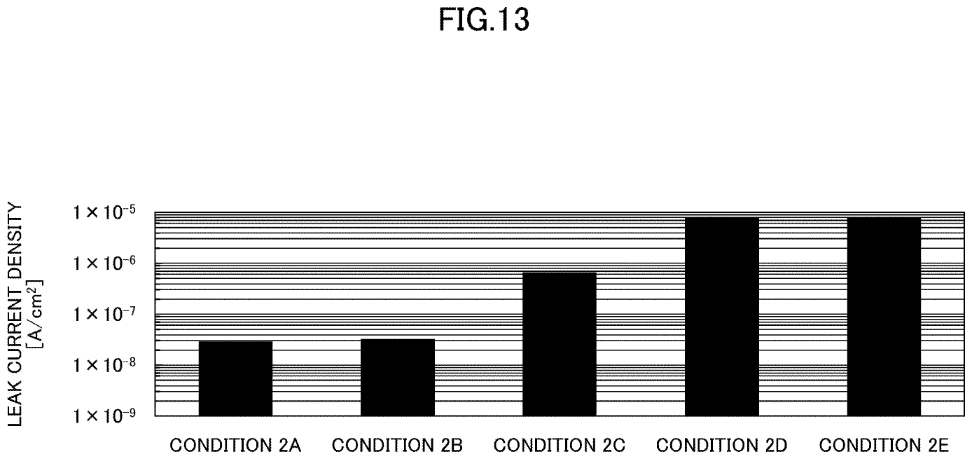

FIG. 13 is a graph illustrating the leak current density of the silicon oxide film. Specifically, the graph of FIG. 13 illustrates the leak current densities of the silicon oxide film under the respective conditions for modifying the silicon oxide film. That is, the graph of FIG. 13 illustrates the leak current densities [A/cm²] of the silicon oxide film modified under the conditions 2A, 2B, 2C, 2D, and 2E in order from the left.

As illustrated in FIG. 13, the leak current densities of the silicon oxide film modified under the conditions 2A, 2B, 2C, 2D, and 2E were 2.8×10⁻⁸ A/cm², 3.3×10⁻⁸ A/cm², 6.4×10⁻⁷ A/cm², 6.9×10⁻⁶ A/cm², and 7.3×10⁻⁶ A/cm², respectively.

The leak current density of the silicon oxide film under the conditions 2A and 2B was greatly reduced compared to the leak current density of the silicon oxide film under the condition 2E, while the leak current density of the silicon oxide film under the conditions 2C and 2D was slightly reduced compared to the leak current density of the silicon oxide film under the condition 2E. This result indicates that the leak current of the silicon oxide film can be reduced by performing both the cyclic plasma process and the nitrogen plasma process on the silicon oxide film compared to performing the cyclic plasma process alone or the nitrogen plasma process alone on the silicon oxide film.

Substantially no difference in the leak current density of the silicon oxide film was found between the condition 2A and the condition 2B. This result indicates that the leak current of the silicon oxide film can be reduced to the same extent between when the nitrogen plasma process is performed after the cyclic plasma process and when the nitrogen plasma process is performed before the cyclic plasma process.

The embodiments disclosed above should be considered illustrative and not restrictive in all respects. Omissions, substitutions, and modifications may be made to the above-described embodiments in various ways without departing from the scope and intent of the claims recited.

The above-described embodiments have been described using a case in which the silicon oxide film is formed using the metal catalyst gas and the silanol-containing gas. However, the present disclosure is not limited to this. For example, the silicon oxide film may be formed using a silicon-containing gas and an oxidizing agent.

The above-described embodiments have been described using a case in which the hydrogen-containing gas is a hydrogen gas, the nitrogen-containing gas is a nitrogen gas, and the inert gas is an argon gas. However, the present disclosure is not limited to this. The nitrogen-containing gas may be an ammonia gas. The inert gas may be a noble gas other than the argon gas, such as a helium gas or the like.

According to the present disclosure, the electrical characteristics of the silicon oxide film can be improved.

What is claimed is:

1. A method for modifying a silicon oxide film, the method comprising:
providing a substrate over which a silicon oxide film is formed; and
modifying the silicon oxide film, wherein
the modification of the silicon oxide film includes:
(a) exposing a surface of the silicon oxide film to a first plasma formed from a first gas containing a hydrogen-containing gas;
(b) exposing the surface of the silicon oxide film to a second plasma formed from a second gas free from a hydrogen-containing gas and containing an inert gas; and
(c) exposing the surface of the silicon oxide film to a third plasma formed from a third gas containing a nitrogen-containing gas.

2. The method for modifying the silicon oxide film according to claim 1, wherein
(b) is performed after (a), and (c) is performed after (b).

3. The method for modifying the silicon oxide film according to claim 1, wherein
the modification of the silicon oxide film further includes:
(d) repeatedly performing a process of (a) and (b).

4. The method for modifying the silicon oxide film according to claim 1, wherein
the modification of the silicon oxide film further includes:
(e) repeatedly performing a process of (a), (b), and (c).

5. The method for modifying the silicon oxide film according to claim 1, wherein
the first plasma is maintained when (a) is switched to (b) or the second plasma is maintained when (b) is switched to (a).

6. The method for modifying the silicon oxide film according to claim 1, wherein
the first plasma is stopped when (a) is switched to (b) or the second plasma is stopped when (b) is switched to (a).

7. The method for modifying the silicon oxide film according to claim 1, wherein
the second plasma is maintained when (b) is switched to (c) or the third plasma is maintained when (c) is switched to (b).

8. The method for modifying the silicon oxide film according to claim 1, wherein
the second plasma is stopped when (b) is switched to (c) or the third plasma is stopped when (c) is switched to (b).

9. The method for modifying the silicon oxide film according to claim 1, wherein
the first gas further contains the inert gas.

10. The method for modifying the silicon oxide film according to claim 9, wherein
supply of the inert gas is maintained when (a) is switched to (b) or when (b) is switched to (a).

11. The method for modifying the silicon oxide film according to claim 1, wherein
the third gas further contains the inert gas.

12. The method for modifying the silicon oxide film according to claim 11, wherein
the third gas further contains the hydrogen-containing gas.

13. The method for modifying the silicon oxide film according to claim 11, wherein
the third gas is free from the hydrogen-containing gas.

14. The method for modifying the silicon oxide film according to claim 12, wherein
a ratio of a flow rate of the nitrogen-containing gas contained in the third gas is 5% or more and 40% or less.

15. The method for modifying the silicon oxide film according to claim 1, wherein
the hydrogen-containing gas is a hydrogen gas,
the inert gas is an argon gas, and
the nitrogen-containing gas is a nitrogen gas.

16. The method for modifying the silicon oxide film according to claim 1, wherein
the provision of the substrate includes:
supplying a metal catalyst gas to the substrate such that the metal catalyst gas is adsorbed onto a surface of the substrate; and
forming the silicon oxide film by supplying a silanol-containing gas to the substrate such that the silanol-containing gas is adsorbed onto the surface of the substrate and reacted with the metal catalyst gas.

17. The method for modifying the silicon oxide film according to claim 16, wherein
the provision of the substrate includes:
repeatedly performing the adsorption of the metal catalyst gas and the formation of the silicon oxide film.

18. The method for modifying the silicon oxide film according to claim 17, further comprising:
repeatedly performing the adsorption of the metal catalyst gas, the formation of the silicon oxide film, and the modification of the silicon oxide film.

19. The method for modifying the silicon oxide film according to claim 16, wherein
a temperature at which the modification of the silicon oxide film is performed is higher than a temperature at which the adsorption of the metal catalyst gas is performed and higher than a temperature at which the formation of the silicon oxide film is performed.

20. A substrate processing apparatus, comprising:
a processing chamber;
a gas supply configured to supply gas into the processing chamber; and
control circuitry, wherein
the control circuitry is configured to control the gas supply to perform:
providing a substrate over which a silicon oxide film is formed; and
modifying the silicon oxide film, and
the modification of the silicon oxide film includes:
(a) exposing a surface of the silicon oxide film to a plasma formed from a first gas containing a hydrogen-containing gas;
(b) exposing the surface of the silicon oxide film to a plasma formed from a second gas free from a hydrogen-containing gas and containing an inert gas; and
(c) exposing the surface of the silicon oxide film to a plasma formed from a third gas containing a nitrogen-containing gas.
